(19) United States
(12) Patent Application Publication
(10) Pub. No.: US 2025/0364051 A1
(43) Pub. Date: Nov. 27, 2025

(54) MEMORY DEVICE

(71) Applicant: SK hynix Inc., Icheon-si Gyeonggi-do (KR)

(72) Inventors: Jung Hyuk YOON, Icheon-si Gyeonggi-do (KR); Gap Sok DO, Icheon-si Gyeonggi-do (KR)

(73) Assignee: SK hynix Inc., Icheon-si Gyeonggi-do (KR)

(21) Appl. No.: 18/934,973

(22) Filed: Nov. 1, 2024

(30) Foreign Application Priority Data
May 22, 2024 (KR) 10-2024-0066389

(51) Int. Cl. G11C 16/10; G11C 16/30; G11C 16/32

(52) U.S. Cl. CPC G11C 16/102; G11C 16/30; G11C 16/32

(57) ABSTRACT

A memory device includes a memory cell and a write circuit. The memory cell is coupled to a first access line and a second access line. The write circuit applies a first positive voltage to the first access line for a first period, applies a second positive voltage to the first access line for a second period, the second period being subsequent to the first period, and applies a negative voltage to the second access line for the first period and the second period.

### CROSS-REFERENCES TO RELATED APPLICATION

The present application claims priority under 35 U.S.C. § 119(a) to Korean patent application number 10-2024-0066389 filed on May 22, 2024, in the Korean Intellectual Property Office, which application is incorporated herein by reference in its entirety.

### BACKGROUND

### 1. Technical Field

Various embodiments generally relate to a semiconductor device, and, more particularly, to a memory device.

### 2. Related Art

Electronic devices include many electronic components, and among them, a computer system may include many electronic components composed of semiconductors. Among the semiconductor devices constituting the computer system, a host device, such as a processor or a memory controller, can perform data communication with a memory device. The memory device may include a plurality of memory cells, specified by word lines and bit lines, to store data.

A write operation is performed by applying a write voltage to the memory cell, and the durability and write characteristics of the memory cell may be affected by the write voltage. Therefore, a method to suppress degradation of the durability and write characteristics of the memory cell and improve the performance of the write operation may be required.

### SUMMARY

In an embodiment, a memory device may include a memory cell and a write circuit. The memory cell may be coupled to a first access line and a second access line. The write circuit may be configured to apply a first positive voltage to the first access line for a first period, may be configured to apply a second positive voltage to the first access line for a second period, the second period being subsequent to the first period, and may be configured to apply a negative voltage to the second access line for the first period and the second period.

In an embodiment, a memory device may include a memory cell, a write circuit and a control circuit. The memory cell may be coupled to a first access line and a second access line. The write circuit may be configured to apply a write voltage to the memory cell through the first access line and the second access line. The control circuit may be configured to control the write circuit to apply a first write voltage to the memory cell for a predetermined duration when the memory cell is determined to be turned on in response to the first write voltage, and may be configured to control the write circuit to apply a second write voltage to the memory cell for the predetermined duration when the memory cell is determined not to be turned on in response to the first write voltage.

In an embodiment, a memory device may include a memory cell, a write circuit and a control circuit. The memory cell may store data through bi-directional write operation. The write circuit may be configured to apply a write voltage to the memory cell in the bi-directional write operation. The control circuit may be configured to control the write circuit to increase the write voltage in a stepwise manner.

### BRIEF DESCRIPTION OF THE DRAWINGS

FIG. 1 is a block diagram illustrating a configuration of a memory device according to an embodiment of the present disclosure.

FIG. 2 is a waveform diagram to illustrate a write operation of the memory device of FIG. 1 according to an embodiment of the present disclosure.

FIG. 3 is a diagram to illustrate a write operation of sequentially applying four write voltages according to an embodiment of the present disclosure.

FIG. 4 is a block diagram illustrating a configuration of a memory device according to an embodiment of the present disclosure.

FIG. 5 is a waveform diagram to illustrate an operation of the memory device of FIG. 4 for a memory cell in a first state according to an embodiment of the present disclosure.

FIG. 6 is a waveform diagram for illustrating an operation of the memory device of FIG. 4 for a memory cell in a second state according to an embodiment of the present disclosure.

### DETAILED DESCRIPTION

Various embodiments of the present disclosure can perform a write operation with improved performance by suppressing degradation of the durability and write characteristics of a memory cell.

Various embodiments of the present disclosure can perform a write operation with improved performance by ensuring that the memory cells have uniform write characteristics.

Hereinafter, embodiments of the present disclosure will be described in more detail with reference to the accompanying drawings.

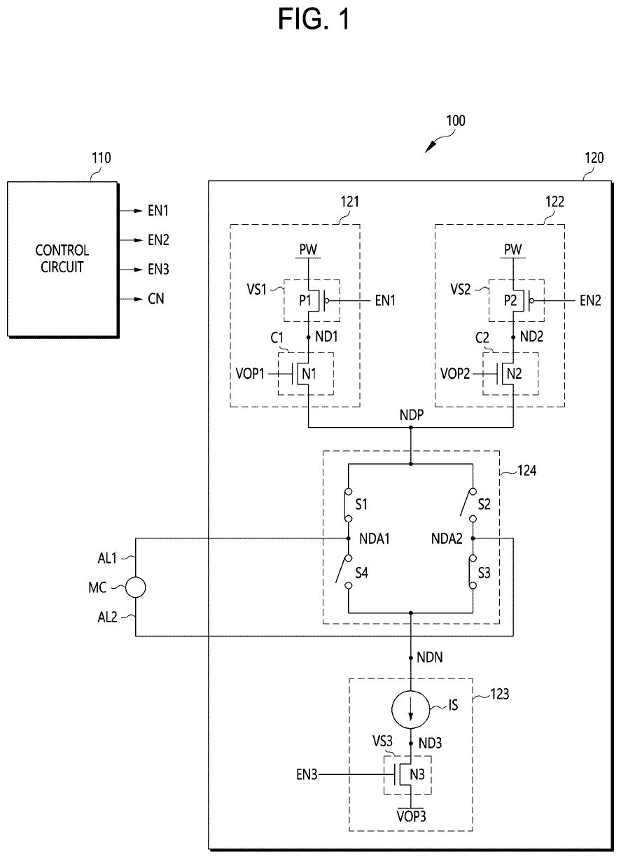

FIG. 1 is a block diagram illustrating a configuration of a memory device 100 according to an embodiment of the present disclosure.

Referring to FIG. 1, the memory device 100 may include a control circuit 110, a write circuit 120, and a memory cell MC.

Based on instructions from an external device, the control circuit 110 may control the write circuit 120 to perform a write operation in response. The control circuit 110 may generate a first enable signal EN1, a second enable signal EN2, a third enable signal EN3, and a connection signal CN in the write operation. The control circuit 110 may generate the first enable signal EN1 in an enabled state during a first period, the second enable signal EN2 in an enabled state during the second period, and a third enable signal EN3 in an enabled state during the first and second periods. The second period may be subsequent to the first period. For example, for the first enable signal EN1 and the second enable signal EN2, a logic low level may signify an enabled status, and a logic high level may signify a disabled status. For the third enable signal EN3, a logic high level may signify an enabled status, and a logic low level may signify a disabled status.

The write circuit 120 may perform a write operation on the memory cell MC in response to control from the control circuit 110. The write circuit 120 may apply a write voltage to the memory cell MC through a first access line AL1 and a second access line AL2 in response to the first enable signal EN1, the second enable signal EN2, the third enable signal EN3, and the connection signal CN received from the control circuit 110. The write voltage may be increased stepwise. The write voltage may include a first write voltage and a second write voltage.

The write circuit 120 may apply the first write voltage to the memory cell MC by applying a first positive voltage to an access line, among the first access line AL1 and the second access line AL2, in response to the first enable signal EN1 and by applying a negative voltage to the other access line, among the first access line AL1 and the second access line AL2, in response to the third enable signal EN3. The first write voltage may be the difference between the first positive voltage applied to one access line and the negative voltage applied to the other access line. The first write voltage may be applied during the first period.

The write circuit 120 may apply the second write voltage to the memory cell MC by applying a second positive voltage to an access line, among the first access line AL1 and the second access line AL2, in response to the second enable signal EN2 and by applying a negative voltage to the other access line, among the first access line AL1 and the second access line AL2, in response to the third enable signal EN3. The second write voltage may be the difference between the second positive voltage applied to one access line and the negative voltage applied to the other access line. The second write voltage may be applied during the second period.

In an embodiment, the write circuit 120 may include a first positive voltage supply circuit 121, a second positive voltage supply circuit 122, a negative voltage supply circuit 123, and an access line connection circuit 124.

The first positive voltage supply circuit 121 may be coupled to a positive voltage node NDP. The first positive voltage supply circuit 121 may apply the first positive voltage to the first access line AL1 or the second access line AL2 through the positive voltage node NDP in response to the first enable signal EN1.

In an embodiment, the first positive voltage supply circuit 121 may include a first voltage switch VS1 and a first clamper C1.

The first voltage switch VS1 may be coupled between a power node PW and a first node ND1. The first voltage switch VS1 may utilize a voltage from the power node PW to drive the first node ND1 in response to the first enable signal EN1. In an embodiment, the first voltage switch VS1 may include a first PMOS transistor P1. A source of the first PMOS transistor P1 may be connected to the power node PW, and a drain may be connected to the first node ND1. The first PMOS transistor P1 may receive the first enable signal EN1 through a gate and may be turned on in response to the first enable signal EN1 being enabled at a logic low level. The first PMOS transistor P1 may utilize a voltage from the power node PW to drive the first node ND1 when turned on.

The first clamper C1 may be coupled between the first node ND1 and the positive voltage node NDP. A first operating voltage VOP1 may be applied to the first clamper C1. The first operating voltage VOP1 may be a positive voltage. The first clamper C1 may utilize the first operating voltage VOP1 to supply the first positive voltage to the positive voltage node NDP when the first enable signal EN1 is enabled. The first positive voltage may be a voltage that turns on the memory cell MC in a first state by being applied to both terminals of the memory cell MC together with a negative voltage applied by the negative voltage supply circuit 123. The difference between the first positive voltage and the negative voltage, i.e., the first write voltage, may be higher than a threshold voltage of the memory cell MC in the first state.

In an embodiment, the first clamper C1 may include a first NMOS transistor N1. A drain of the first NMOS transistor N1 may be connected to the first node ND1 and a source may be connected to the positive voltage node NDP. The first NMOS transistor N1 may receive the first operating voltage VOP1 through a gate. The first positive voltage may be the difference between the first operating voltage VOP1 and a threshold voltage of the first NMOS transistor N1.

The second positive voltage supply circuit 122 may be coupled to the positive voltage node NDP. The second positive voltage supply circuit 122 may apply the second positive voltage to the first access line AL1 or the second access line AL2 through the positive voltage node NDP in response to the second enable signal EN2.

In an embodiment, the second positive voltage supply circuit 122 may include a second voltage switch VS2 and a second clamper C2.

The second voltage switch VS2 may be coupled between the power node PW and a second node ND2. The second voltage switch VS2 may utilize a voltage from the power node PW to drive the second node ND2 in response to the second enable signal EN2. In an embodiment, the second voltage switch VS2 may include a second PMOS transistor P2. A source of the second PMOS transistor P2 may be connected to the power node PW, and a drain may be connected to the second node ND2. The second PMOS transistor P2 may receive the second enable signal EN2 through a gate and may be turned on in response to the second enable signal EN2 being enabled at a logic low level. The second PMOS transistor P2 may utilize a voltage from the power node PW to drive the second node ND2 when turned on.

The second clamper C2 may be coupled between the second node ND2 and the positive voltage node NDP. A second operating voltage VOP2 may be applied to the second clamper C2. The second operating voltage VOP2 may be a positive voltage. The second operating voltage VOP2 may be greater than the first operating voltage VOP1. The second clamper C2 may utilize the second operating voltage VOP2 to supply the second positive voltage to the positive voltage node NDP when the second enable signal EN2 is enabled. The second positive voltage may be a voltage that turns on the memory cell MC in a second state by being applied to both terminals of the memory cell MC together with a negative voltage applied by the negative voltage supply circuit 123. The second positive voltage may be greater than the first positive voltage. The difference between the second positive voltage and the negative voltage, i.e., the second write voltage, may be higher than a threshold voltage of the memory cell MC in the second state.

In an embodiment, the second clamper C2 may include a second NMOS transistor N2. A drain of the second NMOS transistor N2 may be connected to the second node ND2 and a source may be connected to the positive voltage node NDP. The second NMOS transistor N2 may be receive the second operating voltage VOP2 through a gate. The second positive voltage may be the difference between the second operating voltage VOP2 and a threshold voltage of the second NMOS transistor N2.

The negative voltage supply circuit 123 may be coupled to a negative voltage node NDN. The negative voltage supply circuit 123 may apply a negative voltage to the negative voltage node NDN in response to the third enable signal EN3.

In an embodiment, the negative voltage supply circuit 123 may include a third voltage switch VS3 and a current source IS.

The third voltage switch VS3 may be coupled between a third node ND3 and a node of a third operating voltage VOP3. The third operating voltage VOP3 may be a negative voltage. The third voltage switch VS3 may drive the third node ND3 to a negative voltage by using the third operating voltage VOP3 in response to the third enable signal EN3. In an embodiment, the third voltage switch VS3 may include a third NMOS transistor N3. A drain of the third NMOS transistor N3 may be connected to the third node ND3, and a source may be connected to the node of the third operating voltage VOP3. The third NMOS transistor N3 may be receive the third enable signal EN3 through a gate and may be turned on in response to the third enable signal EN3 being enabled with a logic high level.

The current source IS may be coupled between the negative voltage node NDN and the third node ND3. When the third enable signal EN3 is enabled, a negative voltage at the third node ND3 may be delivered as a negative voltage to the negative voltage node NDN through the current source IS. The current source IS may allow a predetermined current to flow from the negative voltage node NDN to the third node ND3 when the memory cell MC is turned on.

In response to a connection signal CN, the access line connection circuit 124 may couple the first access line AL1 and the second access line AL2 to the positive voltage node NDP and the negative voltage node NDN, respectively, or the access line connection circuit 124 may couple the first access line AL1 and the second access line AL2 to the negative voltage node NDN and the positive voltage node NDP, respectively. In a first directional (or forward) write operation, the first access line AL1 and the second access line AL2 may be coupled to the positive voltage node NDP and the negative voltage node NDN, respectively, and the memory cell MC may be applied with a first directional (or forward) write voltage. In a second directional (or reverse) write operation, the first access line AL1 and the second access line AL2 may be coupled to the negative voltage node NDN and the positive voltage node NDP, respectively, and the memory cell MC may be applied with a second directional (or reverse) write voltage.

In an embodiment, the access line connection circuit 124 may include first to fourth switches S1 to S4 operable in response to the connection signal CN. The first switch S1 may be coupled between the positive voltage node NDP and a first access node NDA1. The second switch S2 may be coupled between the positive voltage node NDP and a second access node NDA2. The third switch S3 may be coupled between the second access node NDA2 and the negative voltage node NDN. The fourth switch S4 may be coupled between the first access node NDA1 and the negative voltage node NDN. The first access node NDA1 may be coupled to the first access line AL1, and the second access node NDA2 may be coupled to the second access line AL2.

In response to the connection signal CN, the first switch S1 and the third switch S3 may be turned on together, at which time the second switch S2 and the fourth switch S4 may be turned off. FIG. 1 illustrates an exemplary case where the first switch S1 and the third switch S3 are turned on and the second switch S2 and the fourth switch S4 are turned off to couple the first access node NDA1 and the second access node NDA2 to the positive voltage node NDP and the negative voltage node NDN, respectively.

In response to the connection signal CN, the second switch S2 and the fourth switch S4 may be turned on together, while the first switch S1 and the third switch S3 may be turned off. By turning on the second switch S2 and the fourth switch S4 and turning off the first switch S1 and the third switch S3, the first access node NDA1 and the second access node NDA2 may be coupled to the negative voltage node NDN and the positive voltage node NDP, respectively.

In an embodiment, the connection signal CN may include a plurality of signals corresponding to the first to fourth switches S1 to S4, respectively.

The memory cell MC may be coupled to the first access line AL1 and the second access line AL2. A current may flow through the memory cell MC when the memory cell MC is turned on in response to a write voltage applied through the first access line AL1 and the second access line AL2 in a write operation and may store data through a change in a threshold voltage caused by the current.

On the other hand, the memory cell MC may generate an overcurrent at the moment it is turned on. At this time, the memory cell MC may generate a large overcurrent that is greater than the write voltage. If a large overcurrent is generated, the write characteristics and the durability of the memory cell MC may be degraded. According to the present disclosure, because the memory device 100 applies the first write voltage before applying the second write voltage, the memory cell MC having a threshold voltage lower than the first write voltage may be turned on in response to the first write voltage. The memory cell MC that is turned on in response to the first write voltage may generate a smaller overcurrent than if it is turned on by the second write voltage. In summary, because the overcurrent at the moment the memory cell MC is turned on is suppressed, the performance of the write operation may be improved and the degradation of the durability of the memory cell MC can be suppressed.

In accordance with an embodiment, a write operation for the memory cell MC may be performed bi-directional. The bi-directional write operation may include a first directional (or forward) write operation and a second directional (or reverse) write operation.

The first directional (or forward) write operation may be performed by coupling the first access line AL1 and the second access line AL2 to the positive voltage node NDP and the negative voltage node NDN as shown in FIG. 1. In the first directional write operation, the memory cell MC may allow current to flow from the first access line AL1 to the second access line AL2 after being turned on in response to the first write voltage in the first direction (or forward direction) or the second write voltage in the first direction (or forward direction).

The second directional (or reverse) write operation may be accomplished by the first access line AL1 and the second access line AL2 being coupled to the negative voltage node NDN and the positive voltage node NDP, respectively. In the second directional write operation, the memory cell MC may allow current to flow from the second access line AL2 to the first access line AL1 after being turned on in response to the first write voltage in the second direction (or reverse direction) or the second write voltage in the second direction (or reverse direction).

In an embodiment, the first access line AL1 may be a word line, and the second access line AL2 may be a bit line. Alternatively, the first access line AL1 may be a bit line, and the second access line AL2 may be a word line.

In an embodiment, the memory cell MC may include selector-only memory (SOM) or self-selecting memory (SSM). The memory cell MC may include dual function material (DFM) and two electrodes. The DFM may include chalcogenide-based material.

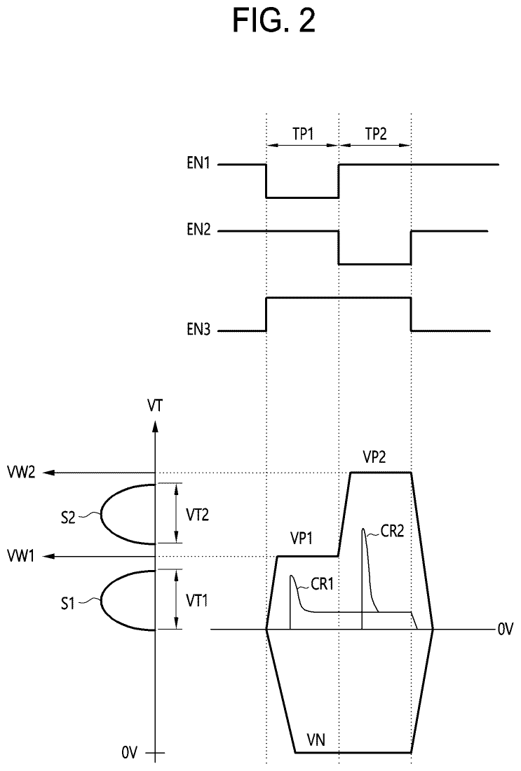

FIG. 2 is a waveform diagram to illustrate a write operation of the memory device 100 of FIG. 1 according to an embodiment of the present disclosure.

Referring to FIG. 2, the memory cells may be in a first state S1 storing first data or in a second state S2 storing second data. The memory cells in the first state S1 may each have a threshold voltage in a range VT1. The memory cells in the second state S2 may each have a threshold voltage in a range VT2.

In a write operation on the one or more memory cells, each of the memory cells needs to be turned on first so that a write voltage that is higher than a threshold voltage is applied to each of the memory cells. The memory device 100 may apply a first write voltage VW1 to the memory cells in a first period TP1 to turn on the memory cells in the first state S1 and may apply a second write voltage VW2 to the memory cells in a second period TP2 to turn on the memory cells in the second state S2.

Specifically, prior to the first period TP1, the first enable signal EN1 and the second enable signal EN2 may be disabled at a logic high level, and the third enable signal EN3 may be disabled at a logic low level. Thus, the first positive voltage supply circuit 121, the second positive voltage supply circuit 122, and the negative voltage supply circuit 123 may all be inoperative.

In the first period TP1, the control circuit 110 may output the first enable signal EN1 in an enabled state at a logic low level and the third enable signal EN3 in an enabled state at a logic high level. The second enable signal EN2 may remain disabled at a logic high level in the first period TP1.

The first voltage switch VS1 may be turned on in response to the first enable signal EN1 in an enabled state at a logic low level. Thus, the first node ND1 may be driven, and the first clamper C1 may supply a first positive voltage VP1 to the positive voltage node NDP. The first positive voltage VP1 may be applied to the memory cell MC through the first access line AL1. Further, the third voltage switch VS3 may be turned on in response to the third enable signal EN3, which is enabled at a logic high level. Thus, the negative voltage VN may be applied to the memory cell MC through the second access line AL2. As a result, the first write voltage VW1, corresponding to the difference between the first positive voltage VP1 and the negative voltage VN, may be applied to the memory cell MC.

The memory cell MC in the first state S1 may have a threshold voltage that is lower than the first write voltage VW1 and may therefore be turned on in response to the first write voltage VW1 in the first period TP1. For example, when the first positive voltage VP1 is +4V and the negative voltage VN is-5V, the first write voltage VW1 may be 9V. Thus, a memory cell MC having a threshold voltage of 8 V may be turned on in response to the first write voltage VW1. A first current CR1 may flow through the memory cell MC that is turned on in response to the first write voltage VW1.

On the other hand, a memory cell MC in the second state S2 may have a threshold voltage that is higher than the first write voltage VW1 and thus might not be turned on in response to the first write voltage VW1 in the first period TP1. For example, when the first positive voltage VP1 is +4 V and the negative voltage VN is −5 V, a memory cell MC having a threshold voltage of 12 V might not be turned on in response to the first write voltage VW1.

Then, in the second period TP2, the control circuit 110 may output the second enable signal EN2 in an enabled state at a logic low level and may continue to output the third enable signal EN3 in an enabled state at a logic high level. In the second period TP2, the control circuit 110 may output the first enable signal EN1 in a disabled state at a logic high level.

The first voltage switch VS1 may be turned off in response to the first enable signal EN1 in a disabled state at a logic high level. The second voltage switch VS2 may be turned on in response to the second enable signal EN2 in an enabled state at a logic low level. Thus, the second node ND2 may be driven, and the second clamper C2 may supply a second positive voltage VP2 to the positive voltage node NDP. The second positive voltage VP2 may be applied to the memory cell MC through the first access line AL1. The negative voltage VN may continue to be applied through the second access line AL2 as the third voltage switch VS3 remains turned on.

The memory cell MC in the second state S2 may have a threshold voltage that is higher than the first write voltage VW1 but lower than the second write voltage VW2 so it may be turned on in response to the second write voltage VW2 in the second period TP2. For example, when the second positive voltage VP2 is +9V and the negative voltage VN is −5V, the second write voltage VW2 may be 14V. Thus, a memory cell MC having a threshold voltage of 12 V may be turned on in response to the second write voltage VW2. A second current CR2 may flow through the memory cell MC that is turned on in response to the second write voltage VW2.

Meanwhile, a memory cell MC in the first state S1 may remain turned on from the first period TP1 to the second period TP2.

Therefore, the first current CR1 may include a smaller overcurrent than the second current CR2. As a result, the overcurrent may be suppressed in the write operation, and thus, the degradation of the write characteristics and the degradation of the durability of the memory cell MC due to the overcurrent may be suppressed.

While FIG. 2 illustrates an exemplary first directional (or forward) write operation, a second directional (or reverse) write operation may be performed similarly as described above.

In an embodiment, the memory cells may store data by existing in more than two states. The memory device 100 may sequentially apply a number of write voltages to the memory cells MC equal to the number of states of the memory cells in the write operation.

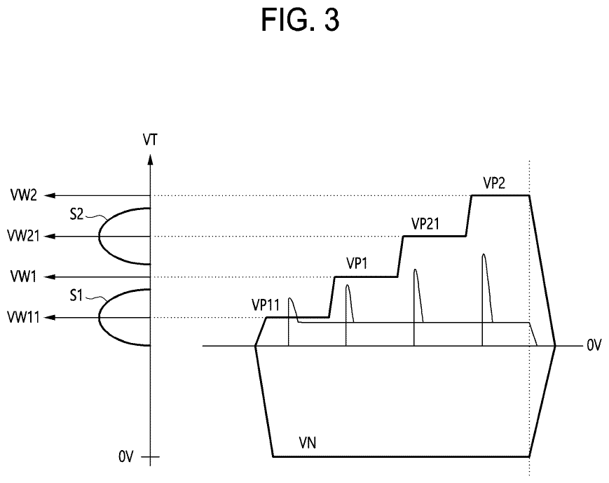

FIG. 3 is a diagram to illustrate a write operation that sequentially applies four write voltages according to an embodiment of the present disclosure.

Referring to FIG. 3, in a write operation for the memory cells in a first state S1 and a second state S2, four write voltages VW11, VW1, VW21, and VW2 may be sequentially applied to turn on the memory cells MC. The write voltages VW11, VW1, VW21, and VW2 may be applied stepwise in order from the lowest write voltage VW11 to the highest write voltage VW2.

Among the memory cells in the first state S1, the memory cell MC having a threshold voltage smaller than the write voltage VW11 may be turned on in response to the write voltage VW11. Among the remaining memory cells in the first state S1, the memory cell MC having a threshold voltage that is less than the first write voltage VW1 may be turned on in response to the first write voltage VW1. Among the memory cells in the second state S2, the memory cell MC having a threshold voltage that is less than the write voltage VW21 may be turned on in response to the write voltage VW21. Among the remaining memory cells in the second state S2, the memory cell MC having a threshold voltage that is less than the second write voltage VW2 may be turned on in response to the second write voltage VW2.

Compared to the operation described with reference to FIG. 2, the memory cell MC having a threshold voltage that is less than the write voltage VW11 may be turned on in response to the write voltage VW11 that is less than the first write voltage VW1, and thus may generate a smaller overcurrent than if it is turned on with the first write voltage VW1. Similarly, the memory cell MC having a threshold voltage that is less than the write voltage VW21 may be turned on in response to the write voltage VW21 that is less than the second write voltage VW2, and thus may generate a smaller overcurrent than if it is turned on with the second write voltage VW2.

To perform the operation described with reference to FIG. 3, the memory device 100 may further include additional positive voltage supply circuits coupled to the positive voltage node NDP. The additional positive voltage supply circuits may be configured to apply positive voltages VP11 and VP21 to the positive voltage node NDP, respectively. Each of the additional positive voltage supply circuits may be configured and operated similarly to the first positive voltage supply circuit 121 or the second positive voltage supply circuit 122. The control circuit 110 may generate enable signals to control each of the additional positive voltage supply circuits. In an embodiment, the memory device 100 may use more than four write voltages to turn on the memory cell MC in a write operation.

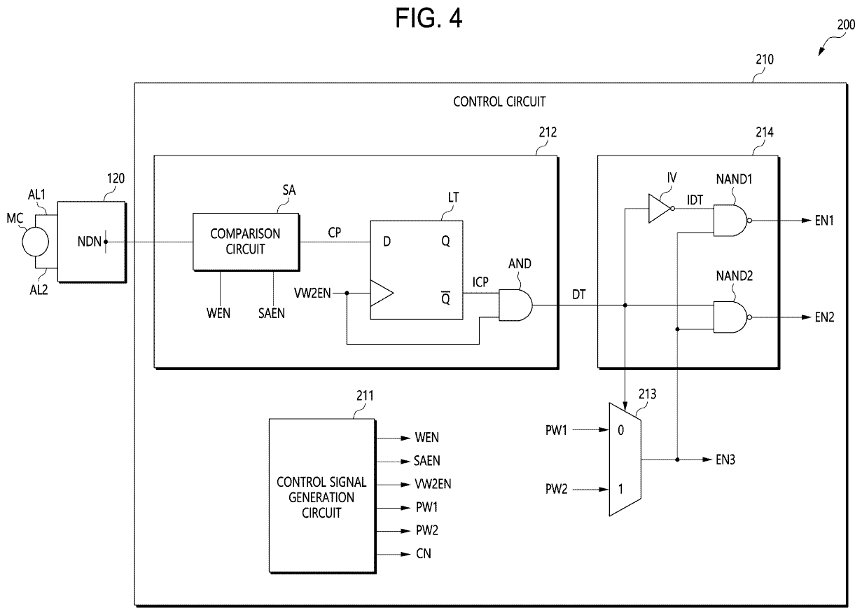

FIG. 4 is a block diagram illustrating a configuration of a memory device 200 according to an embodiment of the present disclosure.

Referring to FIG. 4, the memory device 200 may include a control circuit 210, a write circuit 120, and a memory cell MC. The write circuit 120 and the memory cell MC may be configured identically to the write circuit 120 and the memory cell MC shown in FIG. 1, respectively.

The control circuit 210 may determine whether the memory cell MC is turned on in response to a first write voltage while the write circuit 120 applies the first write voltage to the memory cell MC. The control circuit 210 may control the write circuit 120 to apply the first write voltage to the memory cell MC for a predetermined duration when it is determined that the memory cell MC is turned on in response to the first write voltage. The duration of the first write voltage may refer to a pulse width of the first write voltage. The start of the duration of the first write voltage may be a time at which the first write voltage begins to be applied to the memory cell MC. The control circuit 210 may control the write circuit 120 to no longer apply a write voltage to the memory cell MC after the first write voltage is applied to the memory cell MC for the predetermined duration.

And the control circuit 210 may control the write circuit 120 to apply a second write voltage to the memory cell MC for a predetermined duration when it is determined that the memory cell MC has not been turned on in response to the first write voltage.

In summary, a first write voltage may be applied to the memory cell MC having a threshold voltage that is less than the first write voltage for a predetermined duration. A second write voltage may be applied for a predetermined duration to the memory cell MC having a threshold voltage that is greater than the first write voltage and less than the second write voltage. Because the memory cell MC is subjected to a write voltage that is greater than a threshold voltage only for a predetermined duration, regardless of the threshold voltage, the time for a current to flow in a turned-on state may be constant. As a result, the memory cells may have uniform write characteristics, and the performance of the write operation of the memory device 200 may be further improved.

In an embodiment, the control circuit 210 may include a control signal generation circuit 211, a determination circuit 212, a negative voltage control circuit 213, and a positive voltage control circuit 214.

The control signal generation circuit 211 may determine that a write operation is to be performed in accordance with the control of an external device and may generate a write enable signal WEN, a comparison enable signal SAEN, a second write voltage enable signal VW2EN, a first pulse signal PW1, a second pulse signal PW2, and a connection signal CN. The control signal generation circuit 211 may generate the write enable signal WEN that is in an enabled state while the write operation is being performed. The control signal generation circuit 211 may generate the comparison enable signal SAEN in an enabled state during a determination period. The control signal generation circuit 211 may generate the second write voltage enable signal VW2EN in an enabled state for a predetermined duration after the determination period. The control signal generation circuit 211 may generate the first pulse signal PW1 in an enabled state for the predetermined duration starting from the start of the determination period. The control signal generation circuit 211 may generate the second pulse signal PW2 in an enabled state from the start of the determination period, throughout the determination period, and during the predetermined duration immediately following the determination period. The write enable signal WEN, the comparison enable signal SAEN, the second write voltage enable signal VW2EN, the first pulse signal PW1, the second pulse signal PW2, and the connection signal CN may be enabled at a logic high level and disabled at a logic low level, for example.

By detecting a voltage change of a negative voltage node NDN during the determination period, the determination circuit 212 may determine whether the memory cell MC is turned on in response to a first write voltage and may output a determination signal DT. In other words, the determination circuit 212 may determine whether a second write voltage should be applied to the memory cell MC and may output the determination signal DT. The determination circuit 212 may operate in response to the write enable signal WEN, the comparison enable signal SAEN, and the second write voltage enable signal VW2EN that are output from the control signal generation circuit 211.

The determination circuit 212 may output the determination signal DT in an enabled state when it is determined that the memory cell MC is not turned on in response to the first write voltage. The determination circuit 212 may output the determination signal DT in an enabled state for a predetermined duration after the determination period. The determination circuit 212 may output the determination signal DT in a disabled state when the memory cell MC is determined to be turned on in response to the first write voltage. The determination signal DT may be, for example, enabled at a logic high level and disabled at a logic low level.

In an embodiment, the determination circuit 212 may include a comparison circuit SA, a comparison signal latch LT, and an AND gate.

The comparison circuit SA may output a comparison signal CP in response to the write enable signal WEN and the comparison enable signal SAEN in response to a change in voltage of the negative voltage node NDN. Because the voltage of the negative voltage node NDN changes in response to the memory cell MC being turned on, the comparison circuit SA may output the comparison signal CP indicating whether the memory cell MC is turned on in response to the first write voltage. For example, in response to the write enable signal WEN in an enabled state and the comparison enable signal SAEN in an enabled state, the comparison circuit SA may output the comparison signal CP in an enabled state when the voltage of the negative voltage node NDN is greater than a reference voltage. The comparison circuit SA may maintain the comparison signal CP in an enabled state until the write enable signal WEN is disabled and may change the comparison signal CP from an enabled state to a disabled state when the write enable signal WEN is disabled. The comparison circuit SA may output the comparison signal CP in a disabled state when the voltage of the negative voltage node NDN is not greater than the reference voltage. The comparison signal CP may be, for example, enabled at a logic high level and disabled at a logic low level.

In an embodiment, the comparison circuit SA may include an operational amplifier and a latch. The operational amplifier may operate in response to the comparison enable signal SAEN, a non-inverting node of the operational amplifier may be coupled to the negative voltage node NDN, and a reference voltage may be applied to an inverting node of the operational amplifier. The latch may store an output of the operational amplifier and may output the output as the comparison signal CP.

The comparison signal latch LT may store the comparison signal CP and may output an inverted comparison signal ICP in response to the second write voltage enable signal VW2EN.

The AND gate may receive the inverted comparison signal ICP and the second write voltage enable signal VW2EN and may output a result of an AND operation based on the inverted comparison signal ICP and the second write voltage enable signal VW2EN as the determination signal DT. Thus, when the memory cell MC is turned on in response to the first write voltage, and the comparison signal CP is output in an enabled state, the AND gate may output the determination signal DT in a disabled state. When the memory cell MC is not turned on in response to the first write voltage so that the comparison signal CP remains disabled for the determination period, the AND gate may output the determination signal DT in an enabled state.

The negative voltage control circuit 213 may output the first pulse signal PW1 or the second pulse signal PW2 as a third enable signal EN3 in response to the determination signal DT. Specifically, the negative voltage control circuit 213 may output the first pulse signal PW1 as the third enable signal EN3 in response to the determination signal DT in a disabled state. The negative voltage control circuit 213 may output the second pulse signal PW2 as the third enable signal EN3 in response to the determination signal DT in an enabled state. In an embodiment, the negative voltage control circuit 213 may be configured as a multiplexer.

The positive voltage control circuit 214 may output a first enable signal EN1 and a second enable signal EN2 in response to the determination signal DT and the third enable signal EN3. Specifically, in response to the determination signal DT in a disabled state and the third enable signal EN3 in an enabled state, the positive voltage control circuit 214 may output the first enable signal EN1 in an enabled state and the second enable signal EN2 in a disabled state. In response to the determination signal DT in an enabled state and the third enable signal EN3 in an enabled state, the positive voltage control circuit 214 may output the first enable signal EN1 in a disabled state and the second enable signal EN2 in an enabled state. In response to the determination signal DT in a disabled state and the third enable signal EN3 in a disabled state, the positive voltage control circuit 214 may output the first enable signal EN1 in a disabled state and the second enable signal EN2 in a disabled state.

In an embodiment, the positive voltage control circuit 214 may include an inverter IV, a first NAND gate NAND1, and a second NAND gate NAND2. The inverter IV may receive the determination signal DT and may output an inverted determination signal IDT. The first NAND gate NAND1 may receive the inverted determination signal IDT and the third enable signal EN3 and may output a result of the NAND operation on the inverted determination signal IDT and the third enable signal EN3 as the first enable signal EN1. The second NAND gate NAND2 may receive the determination signal DT and the third enable signal EN3 and may output a result of the NAND operation based on the determination signal DT and the third enable signal EN3 as the second enable signal EN2.

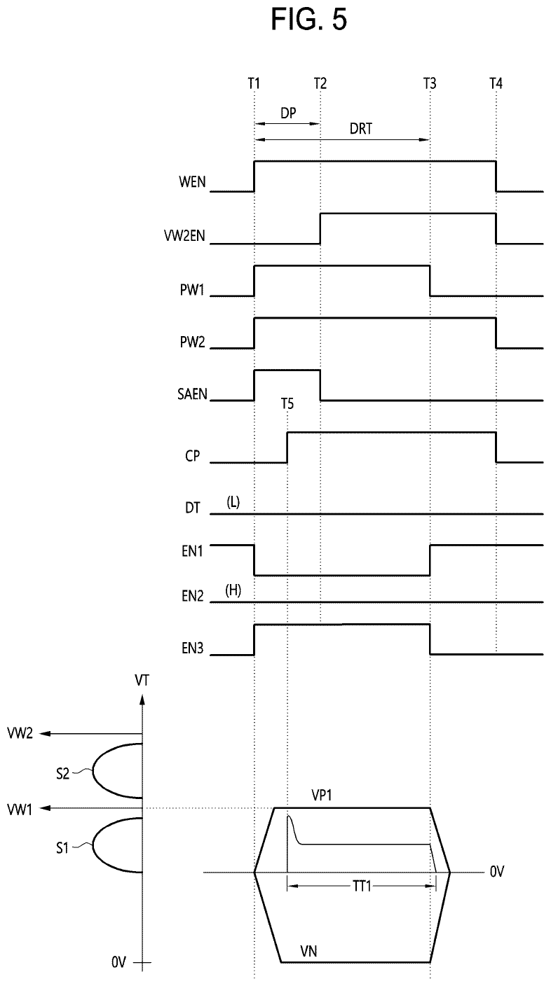

FIG. 5 is a waveform diagram to illustrate an operation of the memory device 200 of FIG. 4 for a memory cell MC in a first state S1, according to an embodiment of the present disclosure. The period from time point T1 to time point T2 may be a determination period DP.

Referring to FIG. 5, the memory cell MC may be in a turned-off state prior to the time point T1 when the write operation begins. Prior to the time point T1, the write enable signal WEN, the second write voltage enable signal VW2EN, and the comparison enable signal SAEN may be in a disabled state at a logic low level. Therefore, the determination circuit 212 may output the determination signal DT in a disabled state at a logic low level.

The negative voltage control circuit 213 may output the first pulse signal PW1 in a disabled state at a logic low level as the third enable signal EN3 in response to the determination signal DT in a disabled state at a logic low level.

Further, in response to the determination signal DT in a disabled state at a logic low level and the third enable signal EN3 in a disabled state at a logic low level, the positive voltage control circuit 214 may output the first enable signal EN1 in a disabled state at a logic high level and the second enable signal EN2 in a disabled state at a logic high level.

At time point T1, the control signal generation circuit 211 may output the write enable signal WEN and the comparison enable signal SAEN in an enabled state at a logic high level. The determination circuit 212 may output the determination signal DT in a disabled state at a logic low level in response to the second write voltage enable signal VW2EN, which is still in a disabled state at a logic low level.

Then, the control signal generation circuit 211 may output the first pulse signal PW1 and the second pulse signal PW2 in an enabled state at a logic high level. The negative voltage control circuit 213 may output the first pulse signal PW1 in an enabled state at a logic high level as the third enable signal EN3 in response to the determination signal DT in a disabled state at a logic low level.

In response to the determination signal DT in a disabled state at a logic low level and the third enable signal EN3 in an enabled state at a logic high level, the positive voltage control circuit 214 may output the first enable signal EN1 in an enabled state at a logic low level and the second enable signal EN2 in a disabled state at a logic high level.

The write circuit 120 may apply the first positive voltage VP1 to the first access line AL1 in response to the first enable signal EN1 in an enabled state at a logic low level. At the same time, the write circuit 120 may apply the negative voltage VN to the second access line AL2 in response to the third enable signal EN3 in an enabled state at a logic high level. The memory cell MC in the first state S1 may be turned on in response to the first write voltage VW1, i.e., the difference between the first positive voltage VP1 applied to the first access line AL1 and the negative voltage VN applied to the second access line AL2.

The voltage at the negative voltage node NDN may be changed by turning on the memory cell MC in the first state S1 and allowing a current to flow through the memory cell MC. At time point T5, the comparison circuit SA may detect a voltage change of the negative voltage node NDN and may output the comparison signal CP that is enabled at a logic high level. The comparison signal CP may remain enabled at a logic high level until the write enable signal WEN is disabled at the time point T4. Thus, the determination signal DT may remain disabled at a logic low level.

At time point T2, the control signal generation circuit 211 may output the comparison enable signal SAEN that is disabled at a logic low level. The control signal generation circuit 211 may output the second write voltage enable signal VW2EN in an enabled state at a logic high level. However, because the memory cell MC in the first state S1 is determined to have been turned on in response to the first write voltage VW1 in the determination period DP, an operation of applying the second write voltage VW2 by the second write voltage enable signal VW2EN might not be activated.

At time point T3, as the first pulse signal PW1 transitions from being enabled at a logic high level to being disabled at a logic low level, the negative voltage control circuit 213 may change the third enable signal EN3 from being enabled at a logic high level to being disabled at a logic low level. As the third enable signal EN3 transitions from being enabled at a logic high level to being disabled at a logic low level, the positive voltage control 214 may change the first enable signal EN1 from being enabled at a logic low level to being disabled at a logic high level.

The write circuit 120 may stop applying the first positive voltage VP1 in response to the first enable signal EN1 being disabled at a logic high level. The write circuit 120 may also stop applying the negative voltage VN in response to the third enable signal EN3, which is disabled at a logic low level. Thus, the memory cell MC may be turned off.

As a result, the first write voltage VW1 may be applied to the memory cell MC in the first state S1 during a duration DRT, and the memory cell MC may be turned on for a time TT1 to allow current to flow through.

At time T4, the write enable signal WEN, the second write voltage enable signal VW2EN, and the second pulse signal PW2 may be disabled at a logic low level.

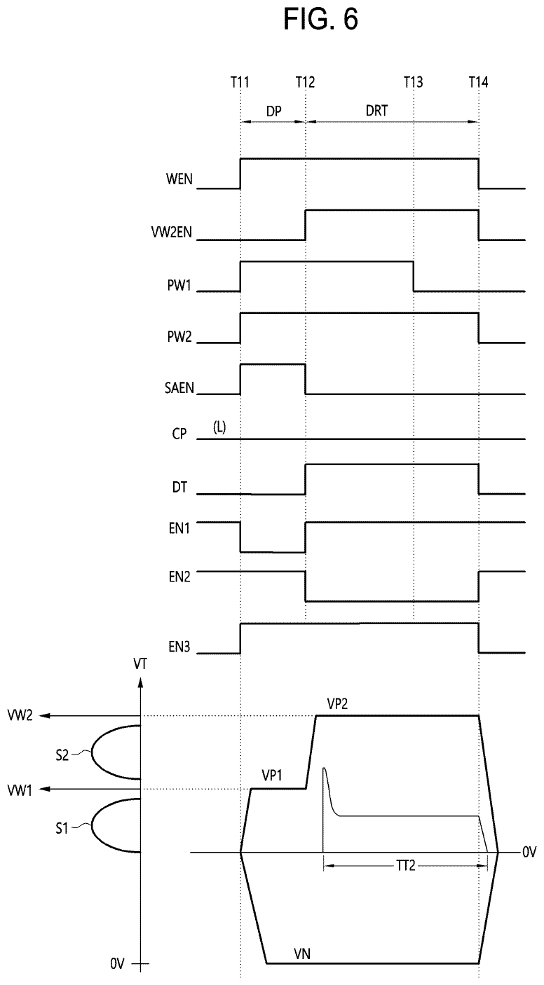

FIG. 6 is a waveform diagram to illustrate an operation of the memory device 200 of FIG. 4 for a memory cell MC in a second state S2, according to an embodiment of the present disclosure.

Referring to FIG. 6, the write enable signal WEN, the second write voltage enable signal VW2EN, the comparison enable signal SAEN, the first pulse signal PW1, and the second pulse signal PW2 may be the same as described with reference to FIG. 5.

At time point T11, an operation method of the write circuit 120 may be the same as the operation method at the time point T1 described with reference to FIG. 5. Thus, the first positive voltage VP1 may be applied to the memory cell MC in the second state S2 through the first access line AL1, and the negative voltage VN may be applied to the memory cell MC in the second state S2 through the second access line AL2. However, the memory cell MC in the second state S2 might not be turned on in response to the first write voltage VW1.

During the determination period DP, a voltage of the negative voltage node NDN does not change so the comparison signal CP may remain disabled at a logic low level.

At time point T12, the control signal generation circuit 211 may output the comparison enable signal SAEN in a disabled state at a logic low level. The control signal generation circuit 211 may output the second write voltage enable signal VW2EN in an enabled state at a logic high level. Thus, in response to the comparison signal CP in a disabled state at a logic low level and the second write voltage enable signal VW2EN in an enabled state at a logic high level, the determination circuit 212 may output the determination signal DT in an enabled state at a logic high level.

The negative voltage control circuit 213 may output the second pulse signal PW2 in an enabled state at a logic high level as the third enable signal EN3 in response to the determination signal DT in an enabled state at a logic high level.

In response to the determination signal DT in an enabled state at a logic high level and the third enable signal EN3 in an enabled state at a logic high level, the positive voltage control circuit 214 may output the first enable signal EN1 in a disabled state at a logic high level and the second enable signal EN2 in an enabled state at a logic low level.

The write circuit 120 may apply the second positive voltage VP2 to the first access line AL1 in response to the second enable signal EN2 in an enabled state at a logic low level. At the same time, the write circuit 120 may apply the negative voltage VN to the second access line AL2 in response to the third enable signal EN3 in an enabled state at a logic high level. The memory cell MC in the second state S2 may be turned on and may allow a current to flow in response to the second write voltage VW2, i.e., the difference between the second positive voltage VP2 applied to the first access line AL1 and the negative voltage VN applied to the second access line AL2. Meanwhile, because the comparison enable signal SAEN is in a disabled state at a logic low level, the comparison signal CP may remain in a disabled state at a logic low level even though current is flowing.

At time point T14, as the second pulse signal PW2 transitions from being enabled at a logic high level to being disabled at a logic low level, the negative voltage control circuit 213 may change the third enable signal EN3 from being enabled at a logic high level to being disabled at a logic low level. As the third enable signal EN3 transitions from being enabled at a logic high level to being disabled at a logic low level, the positive voltage control 214 may change the second enable signal EN2 from being enabled at a logic low level to being disabled at a logic high level.

The write circuit 120 may stop applying the second positive voltage VP2 in response to the second enable signal EN2 being disabled at a logic high level. The write circuit 120 may also stop applying the negative voltage VN in response to the third enable signal EN3, which is disabled at a logic low level. Thus, the memory cell MC may be turned off.

As a result, the first write voltage VW1 may be applied to the memory cell MC in the second state S2 during a determination time, i.e., a time of the determination period DP, the second write voltage VW2 may be applied to the memory cell MC during the duration DRT, and the memory cell MC may be turned on for a time TT2 to allow current to flow. Because the time at which the first write voltage VW1 is applied to the memory cell MC in the first state S1 and the time at which the second write voltage VW2 is applied to the memory cell MC in the second state S2 are both equal in duration DRT, the time at which the memory cell MC in the first state S1 is turned on (TT1 in FIG. 5) and the time at which the memory cell MC in the second state S2 is turned on (TT2) may be approximately the same. Thus, the memory cell MC in the first state S1 and the memory cell MC in the second state S2 may have uniform write characteristics, and as a result, the performance of the write operation of the memory device 200 may be improved.

The write operation for the memory cell MC in the first state S1, described with reference to FIG. 5, and the write operation for the memory cell MC in the second state S2, described with reference to FIG. 6, may be performed in parallel and simultaneously.

While FIGS. 5 and 6 illustrate an exemplary first directional (or forward) write operation, a second directional (or reverse) write operation may be performed similarly as described above.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A memory device, comprising:
a memory cell coupled to a first access line and a second access line; and
a write circuit configured to apply a first positive voltage to the first access line for a first period, configured to apply a second positive voltage to the first access line for a second period, the second period being subsequent to the first period, and configured to apply a negative voltage to the second access line for the first period and the second period.

2. The memory device of claim 1, wherein the write circuit comprises:
a first positive voltage supply circuit configured to supply the first positive voltage to the first access line or the second access line through a positive voltage node in response to a first enable signal;
a second positive voltage supply circuit configured to supply the second positive voltage to the first access line or the second access line through the positive voltage node in response to a second enable signal; and
a negative voltage supply circuit configured to supply the negative voltage to the first access line or the second access line through a negative voltage node in response to a third enable signal.

3. The memory device of claim 2, wherein the write circuit further comprises an access line connection circuit configured to, in response to a connection signal, couple the first access line and the second access line to the positive voltage node and the negative voltage node, respectively.

4. The memory device of claim 2, wherein the write circuit further comprises an access line connection circuit configured to, in response to a connection signal, couple the first access line and the second access line to the negative voltage node and the positive voltage node, respectively.

5. The memory device of claim 1, wherein a current flows through the memory cell when the memory cell is turned on in response to a voltage applied through the first access line and the second access line, and
wherein the memory cell stores data through a change in a threshold voltage caused by the current.

6. The memory device of claim 1, further comprising a control circuit configured to output a first enable signal to the write circuit during the first period, configured to output a second enable signal to the write circuit during the second period, and configured to output a third enable signal to the write circuit during the first period and the second period.

7. A memory device, comprising:
a memory cell coupled to a first access line and a second access line;
a write circuit configured to apply a write voltage to the memory cell through the first access line and the second access line; and
a control circuit configured to control the write circuit to apply a first write voltage to the memory cell for a predetermined duration when the memory cell is determined to be turned on in response to the first write voltage and configured to control the write circuit to apply a second write voltage to the memory cell for the predetermined duration when the memory cell is determined not to be turned on in response to the first write voltage.

8. The memory device of claim 7, wherein the write circuit applies the first write voltage to the memory cell by applying a first positive voltage to the first access line and a negative voltage to the second access line and applies the second write voltage to the memory cell by applying a second positive voltage to the first access line and the negative voltage to the second access line.

9. The memory device of claim 7, wherein the write circuit comprises:
a first positive voltage supply circuit configured to supply a first positive voltage to the first access line or the second access line through a positive voltage node in response to a first enable signal;
a second positive voltage supply circuit configured to supply a second positive voltage to the first access line or the second access line through the positive voltage node in response to a second enable signal; and
a negative voltage supply circuit configured to supply a negative voltage to the first access line or the second access line through a negative voltage node in response to a third enable signal.

10. The memory device of claim 9, wherein the write circuit further comprises an access line connection circuit configured to, in response to a connection signal, couple the first access line and the second access line with the positive voltage node and the negative voltage node, respectively.

11. The memory device of claim 9, wherein the write circuit further comprises an access line connection circuit configured to, in response to a connection signal, couple the first access line and the second access line to the negative voltage node and the positive voltage node, respectively.

12. The memory device of claim 7, wherein the control circuit comprises a determination circuit configured to output a determination signal in an enabled state when the memory cell is determined not to be turned on in response to the first write voltage by determining, during a determination period, whether a voltage of a negative voltage node coupled to the first access line is greater than a reference voltage.

13. The memory device of claim 12, wherein the determination signal is in the enabled state for the duration after the determination period.

14. The memory device of claim 12, wherein the control circuit further comprises a negative voltage control circuit configured to output a first pulse signal or a second pulse signal as a third enable signal in response to the determination signal, and
wherein the first pulse signal is in an enabled state for the predetermined duration from a start of the determination period, and the second pulse signal is in an enabled state from the start of the determination period, throughout the determination period, and during the predetermined duration immediately following the determination period.

15. The memory device of claim 14, wherein the negative voltage control circuit outputs the first pulse signal as the third enable signal in response to the determination signal in a disabled state and outputs the second pulse signal as the third enable signal in response to the determination signal in an enabled state.

16. The memory device of claim 14, wherein the control circuit further comprises a positive voltage control circuit configured to, in response to the determination signal in a disabled state and the third enable signal in an enabled state, output a first enable signal in an enabled state and a second enable signal in a disabled state and configured to, in response to the determination signal in an enabled state and the third enable signal in the enabled state, output the first enable signal in a disabled state and the second enable signal in an enabled state.

17. A memory device, comprising:
a memory cell that stores data through bi-directional write operation;
a write circuit configured to apply a write voltage to the memory cell in the bi-directional write operation; and
a control circuit configured to control the write circuit to increase the write voltage in a stepwise manner.

18. The memory device of claim 17, wherein the control circuit controls the write circuit to apply a first write voltage to the memory cell for a first period and to apply a second write voltage to the memory cell for a second period, the second period following the first period.

19. The memory device of claim 17, wherein, when the memory cell is determined not to be turned on in response to a first write voltage during a determination period, the control circuit controls the write circuit to apply a second write voltage to the memory cell for a predetermined duration after the determination period.

20. The memory device of claim 19, wherein, when the memory cell is determined to be turned on in response to the first write voltage, the control circuit controls the write circuit to apply the first write voltage to the memory cell for the duration.

21. The memory device of claim 17, wherein the memory cell is coupled to a first access line and a second access line,
wherein the bi-directional write operation includes a first directional write operation and a second directional write operation, and
wherein the write circuit applies the write voltage to the memory cell by applying a positive voltage to the first access line while applying a negative voltage to the second access line in the first directional write operation and applies the write voltage to the memory cell by applying the positive voltage to the second access line while applying the negative voltage to the first access line in the second directional write operation.
